(19) United States
(12) Patent Application Publication
(10) Pub. No.: US 2007/0254491 A1
(43) Pub. Date: Nov. 1, 2007

(54) Protective layer for a low k dielectric film and methods of forming the same

(75) Inventor: Robin Cheung, Cupertino, CA (US)

Correspondence Address: DUGAN & DUGAN, PC, 55 SOUTH BROADWAY, TARRYTOWN, NY, 10591, US

(73) Assignee: Applied Materials, Inc., Santa Clara, CA (US)

(21) Appl. No.: 11/413,715

(22) Filed: Apr. 29, 2006

(51) Int. Cl. H01L 23/58; H01L 21/31

(52) U.S. Cl. 438/758; 257/635

(57) ABSTRACT

A semiconductor stack having a protective layer formed into a low k dielectric material is provided. The method for forming the protective layer in a low k dielectric material may include plasma etching the low k dielectric material to form Si—OH bonds on a surface of the low k dielectric material, exposing the Si—OH bonds to a silicon containing fluid solution, and replacing the Si—OH bonds with Si—Si bonds generated by the silicon containing fluid solution to form a protective layer on the surface of the low k dielectric material.

### BACKGROUND OF THE INVENTION

1. Field of the Invention

Embodiments of the invention generally relate to improving the dielectric constant of low k films after plasma etching and/or substrate wet cleaning.

2. Description of the Related Art

One of the primary steps in the fabrication of modem semiconductor devices is the formation of metal and dielectric layers on a semiconductor substrate. The layers may be deposited by any one of a number of deposition processes, such as chemical vapor deposition, physical vapor deposition, electrochemical deposition, atomic layer deposition, or any other deposition process used in semiconductor device processing. However, as the size of semiconductor devices continues to shrink, it becomes necessary to use conductive materials having very low resistivities and insulators having very low dielectric constants.

Some dielectric materials used in current semiconductor device processes are generally referred to as low k dielectric materials. These dielectric materials generally have a dielectric constant that is less than about 3, and often times less than about 2.5. The low dielectric constant of such materials operates to reduce the capacitive coupling between adjacent conductors as the size of devices shrinks and the conductors get closer together. Typical low k dielectric materials may include silicon-containing organic polymer materials, such as benzocyclobutene polymers or organosilicate glass. By silicon-containing, it is meant that the organic polymer material contains elemental silicon or silicon compounds, such as Si, SiO₂, or Si₃N₄. One recently developed low k dielectric material is carbon-doped silica, which is referred to as oxidized organo-silane because of its formation process. Applied Materials, Inc. of Santa Clara, Calif. is marketing such a dielectric material and methods and equipment for making it under the trade name of Black Diamond™. Applied Materials is also marketing a second generation low k film under the name Black Diamond™ II, that is a silicon oxide based material that has a UV cure that is used to induce porosity and strengthen the SiO backbone of the material.

While low k films offer numerous benefits, such films often degrade following plasma etching. For example, the effective dielectric constant of a low k film may increase following plasma etching. Accordingly, a need exists for preventing such degradation of low k films.

### SUMMARY OF THE INVENTION

The present invention generally provides methods for forming a protective layer over an outermost surface of a low k film to seal and/or protect the surface of the low k film (e.g., prior to a rinse or wet cleaning step). The methods of the invention may operate to protect the low k film (damaged due to plasma etching) from moisture absorption.

Embodiments of the invention may further provide a semiconductor stack. The stack includes a substrate having conductive features formed thereon, a low k dielectric material positioned at least between the conductive features, and a low k dielectric protective layer formed at an outer surface of the low k dielectric material. The protective layer is formed by exposing a surface of the low k dielectric material to a silicon based solution during a semiconductor device processing step such as a wet cleaning or plasma process.

Embodiments of the invention may further provide a method for forming a protective layer for a low k dielectric material. The method includes plasma etching the low k dielectric material, exposing the low K dielectric material to a silicon containing solution, and forming a protective layer on the surface of the low k dielectric material using the silicon containing solution.

Embodiments of the invention may further provide a method for forming a protective layer for a low k dielectric material. The method includes plasma etching a low k dielectric material having a dielectric constant of less than about 2.5 to generate Si—OH bonds at a surface of the low k dielectric material, exposing the surface of the low k dielectric material to a silicon containing solution, replacing the Si—OH bonds on the surface of the low k dielectric material with Si—Si bonds from the silicon containing solution, and forming a hydrophobic protective layer on the surface of the low k dielectric material with the Si—Si bonds. Numerous other embodiments are provided.

Other features and aspects of the present invention will become more fully apparent from the following detailed description, the appended claims and the accompanying drawings.

### BRIEF DESCRIPTION OF THE DRAWINGS

FIG. 1A illustrates an exemplary low k material layer of the invention in a semiconductor stack;

FIG. 1B illustrates an exemplary dual damascene structure formed within the low k dielectric layer of FIG. 1A using, for example, separate via and trench masking steps with appropriate plasma etchings; and

FIG. 2 is a flowchart illustrating an exemplary method of forming a low k dielectric protection layer of the invention.

### DETAILED DESCRIPTION

Low k films are hydrophobic by nature, as they are formed from SiCO bonds that are inherently hydrophobic. However, low k films are often damaged by plasma etching processes. For example, carbon may be stripped from the low k film in the etching process, which leaves dangling bonds in the surface layer of the low k material that attract hydrogen. Specifically, the SiCO bonds in the surface of the low k material may be replaced with SiOH bonds due to the plasma etching process. The SiOH bonds attract water, which is not a desirable characteristic for a low k dielectric layer, as water absorption increases the dielectric constant of the layer. Potential sources of water in semiconductor device processes include the processing atmosphere, wet polishing steps, wet cleaning steps, etc. Therefore, after plasma etching, a top portion of the low k film will generally become hydrophilic and will absorb moisture in subsequent processing steps, which is undesirable.

The present invention generally provides a method for forming a protective layer over an outer surface of a low k film. As stated above, the outer layer of a low k film is generally hydrophilic after a plasma etching process and may readily absorb water during subsequent cleaning processes, such as wet cleaning. The protective layer may be as thin as a monolayer, is generally hydrophobic, and operates to seal the surface of the low k film prior to a rinse or cleaning step. Following rinsing, the substrate having the protective layer formed thereon may be dried using an IPA vapor in, for example, a Marangoni drying process. Since the protective layer formed is hydrophobic, using IPA vapor for drying operates to prevent water marks that generally result from wet clean processes. For purposes of this application, the term substrate may include a semiconductor wafer, a glass plate for flat panel displays, a polymer substrate or the like.

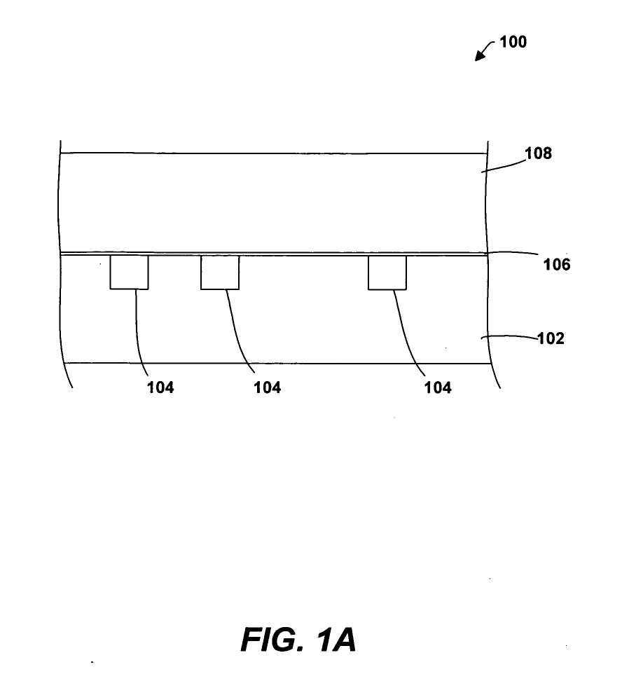

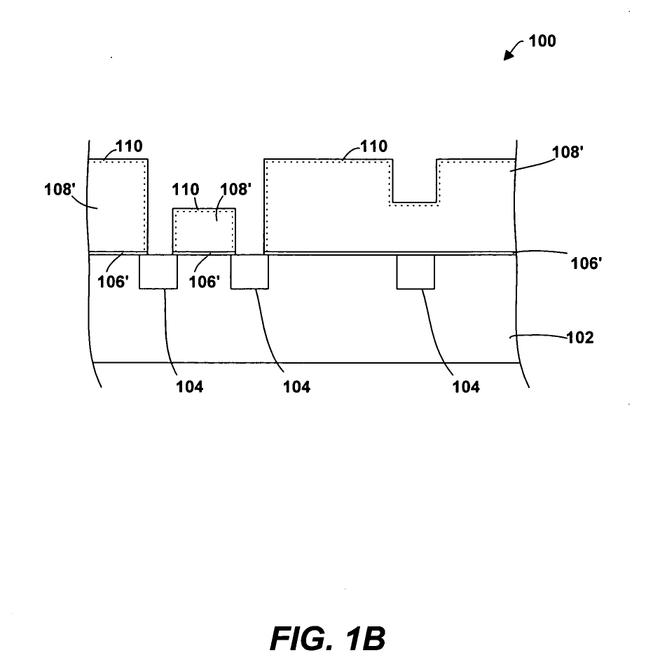

FIG. 1A illustrates an exemplary low k material layer of the invention in a semiconductor stack 100. The semiconductor stack 100 generally includes a substrate or dielectric base layer 102 that has conductive features 104 embedded therein (e.g., damascene copper features). A lining or barrier layer 106 is formed over the conductive features 104 and substrate or dielectric base layer 102, and may, for example, be deposited by a plasma enhanced reaction of an organosilane or organosiloxane compound with an oxidizing gas to form silicon oxynitride. Alternatively, silicon carbide, silicon nitride, or the like may be used for the liner/barrier layer 106. A low k dielectric layer 108 is deposited on the liner/barrier layer 106.

FIG. 1B illustrates an exemplary dual damascene structure formed within the low k dielectric layer 108 using, for example, separate via and trench masking steps with appropriate plasma etchings. Following the etch steps, regions 106′ and 108′ are formed within the liner/barrier layer 106 and low k dielectric layer 108, respectively. A low k dielectric protective layer 110 is formed at (e.g., into or onto) the upper surface and sidewalls of the dielectric layer 108.

Exemplary low k dielectric layers are shown and described in commonly assigned U.S. Pat. Nos. 6,541,367 and 6,596,627, along with US Patent Application Publication No. 2006/0043591, each of which is hereby incorporated by reference in its entirety to the extent not inconsistent with the present invention. More particularly, the above referenced patents and patent publication describe depositing a nano-porous silicon oxide layer having a low dielectric constant. The nano-porous silicon oxide layer is generally produced by a plasma enhanced chemical vapor deposition process or microwave enhanced chemical vapor deposition process of a silicon/oxygen containing material that optionally contains thermally labile organic groups, and by controlled annealing of the deposited silicon/oxygen containing material to form microscopic gas pockets that are uniformly dispersed in a silicon oxide layer. The relative volume of the microscopic gas pockets to the silicon oxide layer is controlled to preferably maintain a closed cell foam structure that provides low dielectric constants after annealing. The nano-porous silicon oxide layers will have dielectric constants less than about 3.0, and preferably less than about 2.5.

The silicon/oxygen low k material is generally chemical vapor deposited by reacting an oxidizable silicon containing compound or mixture that includes an oxidizable silicon component and an unsaturated non-silicon bearing component having thermally labile groups with an oxidizing gas. Exemplary oxidizing gases include but are not limited to oxygen or oxygen containing compounds, such as nitrous oxide, ozone, and carbon dioxide. The oxygen and oxygen containing compounds are preferably dissociated to increase reactivity when necessary to achieve a desired carbon content in the deposited film. RF power can be coupled to the deposition chamber to increase dissociation of the oxidizing compounds. The oxidizing compounds may also be dissociated in a microwave chamber prior to entering the deposition chamber to reduce excessive dissociation of the silicon containing compounds. Deposition of the porous silicon oxide layer can be continuous or discontinuous. Although deposition preferably occurs in a single deposition chamber, the layer can be deposited sequentially in two or more deposition chambers. Furthermore, RF power can be cycled or pulsed to reduce heating of the substrate and promote greater porosity in the deposited film.

In one embodiment of the invention, the process of forming the low k dielectric protection layer 110 may include forming the protection layer 110 during a cleaning or wafer rinsing process (e.g., following plasma etching). More particularly, a water-solulable silicon-type solution or a silicon containing surfactant may be introduced into the cleaning or rinsing fluid during the rinsing or cleaning process. While not wishing to be bound by any particular theory, it is believed that the silicon enhanced solution operates to attach to the SiOH bonds at the surface of the low k dielectric material. The attachment of the silicon enhanced solution to the bonds replaces the OH with a Si bond, e.g., Si—Si bonds are formed, which removes the weaker and less desirable SiOH bonds that are receptive to water and can increase the dielectric constant of the low k material. The reaction at the surface of the low k dielectric layer regions 108′ between the Si and OH bonds operates to form the protection layer 110 at the outer or upper surface and sidewalls of the low k dielectric layer regions 108′ that operates as a moisture barrier layer for the low k dielectric layer regions 108′. The protection layer 110 is generally a hydrophobic layer.

Exemplary water soluble silicon-type solutions may include a fluoroalkyl polyoxyethylene polymer solution, which is commercially available from Ciba Specialty Chemicals, Inc. Another exemplary water soluble silicon-type solution that may be used in embodiments of the invention to form the low k dielectric protection layer is polydimethylsiloxane. Other solutions may be used to form the protective layer.

The formation of the low k dielectric protection layer 110 operates to protect the low k dielectric layer 108 from moisture absorption that is inherent as a result of damage to the outer surface of the low k dielectric layer from a previously conducted plasma etch process. For example, an undamaged low k film is hydrophobic in nature, however, plasma etching converts a top thin layer of the film to a hydrophilic layer that is prone to absorbing moisture that may undesirably increase the dielectric constant of the layer. The formation of the low k dielectric protection layer operates as a moisture barrier, and hence protects the low k film from dielectric constant increases that result from water absorption into the low k dielectric layer following plasma etching.

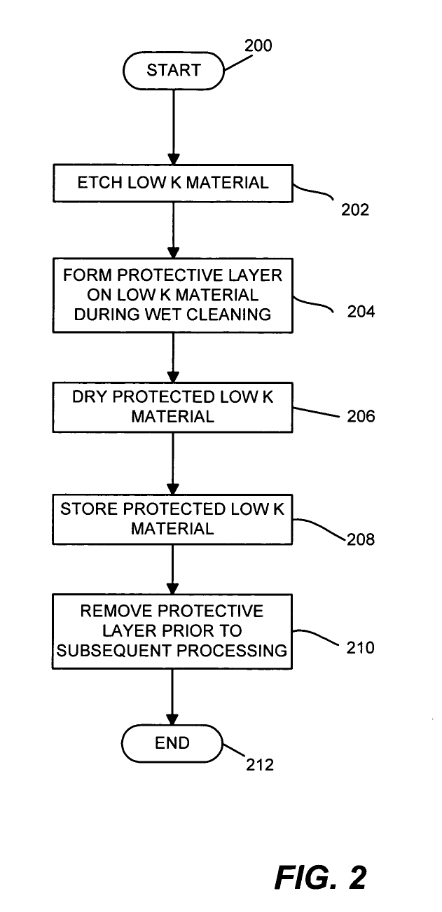

FIG. 2 is a flowchart illustrating an exemplary method of forming a low k dielectric protection layer of the invention. The method of forming the low k dielectric protection layer begins at step 200. It assumed that at step 200, the conductive features, barrier layer, and low k dielectric layer have already been formed. In step 202, the low k dielectric layer is subjected to a plasma etch process. Thereafter, the method continues to step 204, at which a protective layer is formed over the low k dielectric layer during a substrate cleaning step. The substrate cleaning step may be, for example, a wet clean process that is conducted at or near room temperature. More particularly, conventional substrate cleaning processes subject a substrate to a fluid cleaning solution, which may be deionized water or other solvent configured to remove unwanted residual material from the surface of the substrate. The present invention adds the above noted silicon based constituents to the wet cleaning solution. The silicon based constituents that are incorporated into the wet cleaning solution are configured to form the low k dielectric protective layer over the low k dielectric film. For example, the silicon-based constituents are believed to react with the bonds at the surface of the low k dielectric film to replace the weak Si—OH bonds created in the plasma etch process and to form a hydrophobic surface with stronger Si—Si bonds that generate a hydrophobic layer in the outer surface of the dielectric layer.

Once the top layer of the low k dielectric layer has had the Si—OH bonds replaced with the Si—Si bonds (once the protective layer has been formed), then the method may continue to step 206, where the protected low k material/substrate may be rinsed, cleaned, and/or dried. For example, in at least one embodiment of the invention, the protected low k material/substrate may be dried using an IPA drying vapor. At this point in the process, the protected low k material/substrate is ready for storage as indicated by step 208, e.g. with the protective layer on the low k dielectric film, the substrate can be stored for long periods of time before the next processing step without concern for corrosion or moisture damage occurring to the low k dielectric film. (Note that storage of the substrate is optional).

Prior to subsequent processing, the protective layer may be removed from the low k dielectric film (step 210). For example, the protective layer may be exposed to a low power plasma (as described further below) or otherwise removed. In step 212, the method ends.

In an alternative embodiment of the invention, the dielectric layer may be formed without using a fluid cleaning step. More particularly, Applicants note that the protective layer formation process of the invention is not limited to conventional wet or fluid processing cell-type cleaning methods, as the protective layer formation process of the present invention may be incorporated into a plasma processing system. For example, the Si based protection layer formation constituents may be introduced into a plasma processing step for the low k dielectric layer, such as by vaporizing the constituents required to form the low k dielectric layer in water and introducing the vaporized water containing the constituents to a plasma chamber (e.g., during an etch or other step). The Si-based solution in the plasma, in similar fashion to the wet processing steps noted above, is believed to replace the weaker Si—OH bonds with the stronger Si—Si bonds that operate to generate the protective layer.

The process of forming the protective layer in the outer surface of the low k dielectric generally comprises adding or forming a few monolayers in thickness to the low k film, e.g., between about 1 and about 10 monolayers, or between about 2 and about 3 monolayers. The monolayers protect the low k film against moisture absorption and corrosion, and extend the queue time for the substrate indefinitely; whereas unprotected substrates are known to have a queue time of less than about 8 hours before corrosion damages the substrate to the point where device failures are likely. Thus, the protective layer of the invention provides advantages over conventional layers.

As stated, once the protective layer has been formed and the substrate is to be processed in a subsequent processing step, the protective layer is removed from the substrate, as the protective layer may not be compatible or facilitative of the next processing step. In some embodiments, the removal step may include an etch process that is conducted after the protective layer is deposited onto the low k dielectric film, but before the substrate is subjected to the next layer deposition or removal process. More particularly, subsequent processes may not be compatible with the protective layer, and as such, at least a portion of the protective layer may be removed prior to subsequent processing of the substrate (generally after a substantial queue time). To remove at least a portion of the protective layer, an etch chamber may be used. For example, the protective layer may be removed in a low pressure vacuum etch process prior to a subsequently scheduled barrier deposition process. In one particular example, the protective layer may be etch removed and the substrate may be transferred, preferably under vacuum, to a physical vapor deposition chamber for the deposition of a barrier layer such as a tantalum nitride barrier layer. After removal of the protective film, the underlying low k dielectric film may have lost carbon and be susceptible to moisture absorption. As such, the substrate is preferably kept under vacuum and away from moisture once the protective layer is stripped off, e.g., the substrate preferably is kept under vacuum until the next deposition process is conducted on the substrate.

An exemplary etch process that may be used to strip the protective layer may include about 5 seconds of exposure to CF4 plasma in a low power regime to remove the monolayers of the protective material deposited on the low k dielectric material. Other removal processes may be used.

In another embodiment of the invention, the protective layer may be formed in a substrate spin-rinse-dry chamber or a fluid-based substrate cleaning chamber. In this embodiment of the invention, the substrate is generally not subjected to water or other fluids until the protective layer is formed. More particularly, the fluid processing chamber may apply a solution to the substrate that operates to form the protective layer prior to applying any other fluids, as application of fluids prior to the formation of the protective layer may cause degradation of the dielectric constant of the low k material. The fluid solution applied to the substrate to form the protective layer may generally be water based, however, the fluid may contain between about 0.5% and about 1.5% of the silicon based constituents noted above so as to form the protective layer on the low k dielectric surface.

Exemplary fluid processing chambers that may be used for the formation of the low k dielectric protective layer include the Axiom or Oasis cleaning chambers that are commercially available from Applied Materials, Inc. of Santa Clara, Calif. The Oasis system is a 300 mm single-wafer system designed for critical, front end of the line pre-thermal and post-strip wet cleans for sub-130 nm devices. The Oasis uses MegaClean, a full-coverage megasonics unit that enables highly efficient particle removal from both sides of the wafer, and a single-step chemistry called the AM-clean that condenses the traditional two-step RCA (SC1-SC2) process. These advancements result in improved process performance and productivity over traditional wet bench designs, along with enhanced product yield and reduced production cycle-time. The Oasis tool performs horizontal, dual side, wet spin processing. The megasonic energy applied to facilitate particle removal originates beneath the substrate and penetrates through the chemicals and water in the process chamber. More particularly, megasonic cleaning in the Oasis chamber generally includes sending a current through a piezoelectric crystal, causing it to vibrate, which creates bubbles in the process liquid, which in turn remove particles from the wafer surface when the bubbles burst. After the cleaning process, the wafers may be dried, for example, in an IPA vapor drying process or a Marangoni drying process, which is generally illustrated as step 206 in FIG. 2.

The foregoing description discloses only exemplary embodiments of the invention. Modifications of the above disclosed apparatus and methods which fall within the scope of the invention will be readily apparent to those of ordinary skill in the art. For instance, while the present invention has been described primarily with reference to processing semiconductor wafers, it will be understood that any substrate may be similarly processed (e.g., semiconductor wafers, glass plates for flat panel displays, polymer substrates, etc.).

Accordingly, while the present invention has been disclosed in connection with exemplary embodiments thereof, it should be understood that other embodiments may fall within the spirit and scope of the invention, as defined by the following claims.

1. A semiconductor stack, comprising:
a substrate having conductive features formed thereon;
a low k dielectric material positioned at least between the conductive features; and
a low k dielectric protective layer formed at an outer surface of the low k dielectric material, wherein the protective layer is formed by exposing a surface of the low k dielectric material to a silicon based solution during a semiconductor device processing step.

2. The semiconductor stack of claim 1 wherein the semiconductor device processing step comprises a wet cleaning process.

3. The semiconductor stack of claim 1 wherein the semiconductor device processing step comprises a plasma process.

4. The semiconductor stack of claim 1, wherein the protective layer comprises between about 1 and about 3 monolayers formed at the outer surface of the low k dielectric material.

5. The semiconductor stack of claim 4, wherein the protective layer comprises about 1 to 3 monolayers of Si—Si bonds.

6. The semiconductor stack of claim 1, wherein the low k dielectric material has a dielectric constant of less than about 2.5.

7. The semiconductor stack of claim 1, wherein the protective layer is hydrophobic.

8. The semiconductor stack of claim 1, wherein the silicon based solution comprises a fluoroalkyl polyoxyethylene polymer solution or polydimethylsiloxane.

9. The semiconductor stack of claim 1, wherein the protective layer is removable by an etch process.

10. A method for forming a protective layer for a low k dielectric material, comprising:
plasma etching the low k dielectric material;
exposing the low K dielectric material to a silicon containing solution; and
forming a protective layer at the surface of the low k dielectric material using the silicon containing solution.

11. The method of claim 10, wherein the silicon containing solution comprises a fluoroalkyl polyoxyethylene polymer solution or polydimethylsiloxane.

12. The method of claim 10, wherein the silicon containing solution comprises less than about 1% silicon solution and more than about 99% non-reactive fluid.

13. The method of claim 10, wherein forming the protective layer comprises forming the protective layer that is between about 1 and about 3 monolayers thick.

14. The method of claim 10, wherein the protective layer is hydrophobic.

15. The method of claim 10, wherein the low k dielectric material has a dielectric constant of less than about 2.5.

16. The method of claim 10, further comprising removing the protective layer with an etching process and maintaining a dielectric constant of the low k dielectric material at less than about 2.5.

17. The method of claim 16, further comprising maintaining the low k dielectric material in a vacuum until a subsequent deposition process is conducted to cover the low k dielectric material.

18. The method of claim 10, further comprising cleaning and drying the low k dielectric material having the protective layer formed thereon using an IPA vapor drying process.

19. The method of claim 10, wherein exposing the low k dielectric material to a silicon containing solution comprising wet cleaning the low k dielectric material.

20. A method for forming a protective layer for a low k dielectric material, comprising:
plasma etching a low k dielectric material having a dielectric constant of less than about 2.5 to generate Si—OH bonds at a surface of the low k dielectric material;
exposing the surface of the low k dielectric material to a silicon containing solution;
replacing the Si—OH bonds on the surface of the low k dielectric material with Si—Si bonds from the silicon containing solution; and
forming a hydrophobic protective layer on the surface of the low k dielectric material with the Si—Si bonds.

21. The method of claim 20, wherein the protective layer has a thickness of between about 1 monolayer and about 3 monolayers.

22. The method of claim 20, wherein the silicon containing solution comprises less than about 1% of a fluoroalkyl polyoxyethylene polymer solution or polydimethylsiloxane.

23. The method of claim 20, further comprising removing the protective layer and maintaining the dielectric constant of the low k dielectric material at less than about 2.5.

24. The method of claim 20, further comprising IPA drying the protective layer.

25. The method of claim 20, wherein the forming step is conducted in a room temperature fluid processing step.

26. A method for forming a protective layer for a low k dielectric material, comprising:
plasma etching the low k dielectric material in a plasma chamber;
exposing the low k dielectric material to a silicon containing vapor within the plasma chamber; and
forming a protective layer at the surface of the low k dielectric material using the silicon containing vapor.

27. The method of claim 26 wherein the protective layer if formed over any top surfaces and sidewalls formed in the low k dielectric during plasma etching.
